(19) United States
(12) Patent Application Publication
(10) Pub. No.: US 2015/0162471 A1
(43) Pub. Date: Jun. 11, 2015

(54) PHOTOTRANSISTOR DEVICE

(71) Applicant: ELTA SYSTEMS LTD., Ashdod (IL)

(72) Inventor: Noam Cohen, Jerusalem (IL)

(21) Appl. No.: 14/411,707

(22) PCT Filed: Jun. 18, 2013
(86) PCT No.: PCT/IL2013/050519

§ 371 Date: Dec. 29, 2014

(30) Foreign Application Priority Data
Jun. 28, 2012 (IL) 220675

(51) Int. Cl. H01L 31/0352; H01L 27/146; H01L 31/18; H01L 31/11

(52) U.S. Cl. CPC H01L 31/035236; H01L 31/1105; H01L 27/14681; H01L 27/14621; H01L 31/18

(57) ABSTRACT

The present disclosure provides a heterostructure bipolar phototransistor configured for providing an output signal in response to an external impinging light beam. The heterostructure bipolar phototransistor comprises an emitter region and a collector region being doped so that they are of the same conductivity type; a base region interposed between the emitter region and the collector region, the base region being doped so that it is of the opposite conductivity type than the emitter region and the collector region; and an absorption region interposed between the base region and the collector region, wherein the absorption region comprises (or is formed of) a superlattice.

### FIELD AND BACKGROUND

This invention relates to a photodetection device. In particular, it relates to an improvement of a heterostructure bipolar phototransistor device.

Heterostructure bipolar phototransistors (also generally referred to hereinbelow as phototransistors) are known as devices for producing an output electrical current in response to the presence of light. Generally and as described for example in the article “InP/InGaAs heterojunction phototransistors” published in IEEE Journal of Quantum Electronics, vol. 17, pp. 264-269, February 1981, in such structures electron-hole pairs generated by incident light in an absorption region of the phototransistor are separated and collected by the field of the reversed biased base-collector junction leading to current flow in an external circuit. The generated holes are swept into the base and are accumulated there due to a large potential barrier in the valence band at the base emitter heterointerface. To maintain the charge neutrality condition in the forward biased base emitter junction, an injection of electrons occurs from the emitter into the base resulting in an optical gain.

### GENERAL DESCRIPTION

Phototransistors generally enable to obtain radiation sensors with low dark current property. Indeed, due to the discontinuity between the energy bands of the emitter and the base in dark condition, the dark current generated by thermally excited charge carriers can be maintained at a low level.

Phototransistor design however faces several practical constraints. FIG. 1 illustrates the energy gap and lattice constant of the III-V semiconductors compounds practically available to manufacture semiconductor devices. Firstly, as shown on FIG. 1, there is a limited amount of materials that can be used as substrates for growing the semiconductor layers of the phototransistor. Secondly, the energy gap of the semiconductor layer used as an absorption region of the phototransistor determines the spectral band of the absorbed photons thereby limiting the maximal wavelength sensed by the phototransistor. Thirdly, in order to limit the amount of defects to lower the dark current of the phototransistor, it is preferable that the lattice constants of the different layers forming the phototransistor will match with each other. The advantage of lattice matched structure is that it prevents strain between the layers that if relaxed could cause misfit dislocations that would act as recombination centers deteriorating the device performance. As can be illustrated by the following example with reference to FIG. 1, in the case of a substrate formed of InP (Indium Phosphide), no alloys of materials would enable to match the lattice constant of InP and to have a low energy gap (for example inferior to 0.5 eV) so as to sense extended short wavelength infrared radiation.

The applicant has found that including a superlattice absorption region between the base and the collector of the phototransistor eases the design of the phototransistor. This enables to adapt the spectral band of the phototransistor while maintaining a low dark current. Indeed, it is possible to tune the bandgap of a superlattice by adjusting the thickness and composition of individual semiconductor layers.

Therefore, in a first broad aspect the present disclosure provides a heterostructure bipolar phototransistor configured for providing an output signal in response to an external impinging light beam. The heterostructure bipolar phototransistor comprises an emitter region and a collector region being doped so that they are of the same conductivity type; a base region interposed between the emitter region and the collector region, the base region being doped so that it is of the opposite conductivity type than the emitter region and the collector region; and an absorption region interposed between the base region and the collector region, wherein the absorption region comprises (or is formed of) a superlattice.

In some embodiments, the superlattice is configured so as to provide minibands in the valence and conduction bands.

In some embodiments, the minibands are configured to enable detection of infrared radiations with a wavelength up to 2.5 μm at room temperature.

In some embodiments, the superlattice is a type II superlattice.

In some embodiments, the superlattice comprises (or is formed of) an undoped material.

In some embodiments, at least one of the emitter, base, collector and absorption regions are lattice matched to each other.

In some embodiments, the heterostructure bipolar phototransistor further comprises a spacer region between the base region and the emitter region.

In some embodiments, the spacer region is part of the emitter.

In some embodiments, the energy band gap of the absorption region is inferior to the energy band gap of the upper regions of the phototransistor (the collector region and optionally the collector contact region) so that the phototransistor is suitable for being back illuminated i.e. illuminated through the collector. In an embodiment, the energy band gap of the absorption region is inferior to the energy band gap of the emitter region and base region (and optionally of the spacer region and of the emitter contact region) so that the phototransistor is configured to be front illuminated i.e. illuminated through the emitter. In some embodiments, the energy gap of the superlattice absorption region is the smallest of the heterostructure so that the phototransistor is suitable to be used either in front illumination or in back illumination.

In some embodiments, the heterostructure bipolar phototransistor further comprises a first contact region located above the emitter and configured for providing electric contact with the emitter region and a second contact region located below the collector and configured for providing electric contact with the collector region.

In another aspect, the present disclosure provides a phototransistor matrix comprising an array of phototransistors suitable for being back illuminated as previously described. At least some of said phototransistors share at least one of a common absorption region and a common collector region and the phototransistor matrix further comprises: a first contact region configured for providing electric contact to the common collector region; and a plurality of second contact regions configured for providing electric contact to at least some of the emitters of the phototransistors. The phototransistors may be arranged in a rectangular, circular or any planar shape. This configuration enables to hybridize the phototransistor matrix with a readout circuit providing negative bias (standard readout circuit commercially available) to the plurality of second contact regions. The readout circuit may be placed on the top of the phototransistor matrix (configured to contact the plurality of second contact regions). It is to be noted that regular phototransistors are generally illuminated through the emitter thereby preventing the use of standard readout circuit (generally made of non transparent silicon) on the emitter.

The wavelength range of 1.8-2.5 μm might be of special interest to enable concurrent or sequential detection of signals associated with reflection of ambient IR radiation from an object being imaged and also IR emission from said object. In order to address said wavelength band, a detection system (e.g. night vision system) comprising the above-described phototransistor or phototransistor matrix may further include an appropriate spectral filter filtering out radiations with a wavelength inferior to 1.8 μm.

Thus, in another aspect, the present disclosure provides a night vision system for imaging an object, comprising: a phototransistor matrix as previously described; an optical system configured for collecting light and focusing the collected light onto the phototransistor matrix; and a spectral filter located in an optical path of light propagating toward the phototransistor matrix, said spectral filter configured and operable to selectively filter out light of wavelength shorter than a predetermined value, thereby gradually shifting operation of the night vision system from mostly reflection mode to a combined reflection and thermal mode to allow the night vision system to detect light reflected from and emitted by the object being imaged. In one embodiment, this predetermined value may be of about 1.8 μm.

In another aspect, the present disclosure discloses a method of fabrication of a phototransistor comprising: growing sequentially on a substrate a collector contact region, a collector region, an absorption region, a base region, an emitter region and an emitter contact region. The emitter region and the collector region are doped so that they are of the same conductivity type. The base region is doped so that it is of the opposite conductivity type than the emitter region and the collector region. The absorption region comprises (or is formed of) a superlattice.

In some embodiments, the superlattice comprises (or is formed of) absorbing type II superlattice layers.

In some embodiments, the superlattice is configured so that an energy band gap between mini-bands in the valence and conduction bands of the superlattice enables detection of infrared radiations with a wavelength up to 2.5 μm at room temperature.

In some embodiments, the phototransistor is configured for being back illuminated through the common contact region.

In some embodiments, the superlattice is formed of an undoped material. In some embodiments, the energy band gap of the absorption region is inferior to the energy band gap of the collector region and of the collector contact region so that the phototransistor is suitable for being back illuminated.

It is generally noted that the applicant has also found that the use of lattice matched alloys enables to lower dark current. Further, the use of InGaAs (Indium Gallium Arsenide)/GaAsSb (Gallium Arsenide Antimonide) type II superlattice enables extended Short Wavelength Infrared (SWIR) detection. Additionally, the use of a GaAsSb base (rather than InGaAs) provides continuity of the conduction band between the base and collector for better transport of electrons and larger energy gap between the base and the emitter in the valence band for better confinement of optically generated holes to achieve higher optical gain. Furthermore, the use of InP emitter provides optimal charge carriers transport. Eventually, the use of an InAlAs spacer between the emitter and base provides improvement of emitter injection efficiency by reduction of tunneling recombination caused by electron pile at the InP-GaAsSb emitter base hetero junction as well as improvement of the interface quality of the InP-GaAsSb emitter-base hetero-structure.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1, already described, is a diagram illustrating the energy gap and lattice constant of III-V semiconductors alloys with respect the proportion of materials in said alloys.

FIG. 2 illustrates schematically a phototransistor in an embodiment of the present disclosure.

FIGS. 3A-3B are band diagrams illustrating schematically the energy levels of the valence and conduction bands respectively in dark condition and under illumination condition for a phototransistor according to an embodiment of the present disclosure.

FIG. 4 illustrates schematically a phototransistor array in an embodiment of the present disclosure.

### DETAILED DESCRIPTION OF EMBODIMENTS

Described herein are some examples of phototransistor devices and methods of fabricating said phototransistors.

In the following detailed description, specific details are set forth in order to provide a thorough understanding of the subject matter. However, it will be understood by those skilled in the art that some examples of the subject matter may be practiced without these specific details. In other instances, well-known methods, procedures and components have not been described in detail so as not to obscure the description.

As used herein, the phrase “for example,” “such as”, “for instance” and variants thereof describe non-limiting examples of the subject matter.

Reference in the specification to “one example”, “some examples”, “another example”, “other examples, “one case”, “some cases”, “another case”, “other cases” or variants thereof means that a particular described feature, structure or characteristic is included in at least one example of the subject matter, but the appearance of the same term does not necessarily refer to the same example.

It should be appreciated that certain features, structures and/or characteristics disclosed herein, which are, for clarity, described in the context of separate examples, may also be provided in combination in a single example. Conversely, various features, structures and/or characteristics disclosed herein, which are, for brevity, described in the context of a single example, may also be provided separately or in any suitable sub-combination.

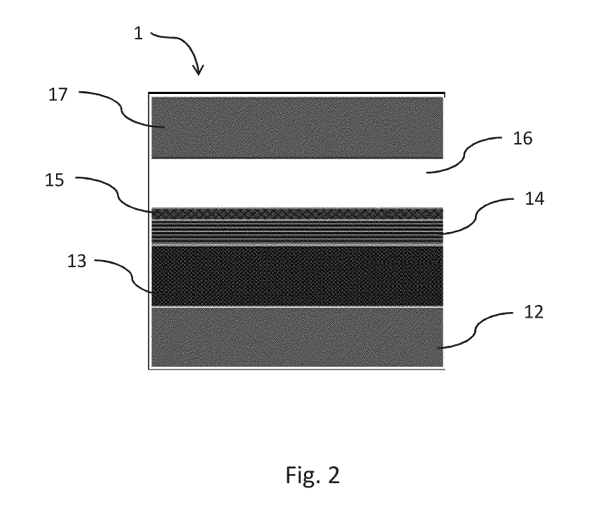

FIG. 2 illustrates the structure of a phototransistor according to an embodiment of the present disclosure. The phototransistor 1 comprises a collector contact layer 12, a collector layer 13, an absorption layer 14, a base layer 15, an emitter layer 16 and an emitter contact layer 17.

The aforementioned layers of the phototransistor 1 may be sequentially grown on a substrate layer (not shown) by suitable growing processes. For example, the substrate may be made of a material such as InP. The substrate layer may be taken off after the phototransistor 1 is fabricated by suitable methods. The substrate layer may further be doped. Doping the substrate may allow direct access of the bottom contact via the substrate, but may cause undesirable absorption.

The collector contact layer 12 and the emitter contact layer 17 may be used to apply a voltage to respectively the collector layer 13 and the emitter layer 16. The collector contact layer 12 and the emitter contact layer 17 may be lattice matched to the substrate in order to limit growing defects in said layers. The collector contact layer 12 and the emitter contact layer 17 may be strongly doped so as to allow ohmic contact. In operation, a negative bias may be applied to the emitter contact layer 17 with respect to the collector contact layer 12 for reversely bias the collector 13 base 15 junction and forward bias the emitter 16 base 15 junction. For example, it is possible to fabricate on an InP substrate a collector contact layer 12 made of 1 μm of n-type doped InP with a doping density of 1.5e18 cm⁻³. The emitter contact layer 17 may be of 0.5 μm of n-type doped InP with a doping density of 1.5e18 cm⁻³.

The collector layer 13 may be formed on the collector contact layer 12 and may be lattice matched to the collector contact layer 12 and the substrate. The collector layer 13 may be doped of the same conductivity type than the emitter layer 16. The collector layer 13 may have an energy gap wider than the energy gap of the absorption layer 14. For example, it is possible to fabricate a collector layer 13 formed on the above collector contact layer example by 0.5 μm of n-doped In0.53Ga0.47As with a doping density of 5e17 cm⁻³.

The absorption layer 14 may be formed on the collector layer 13. The absorption layer 14 may be lattice matched to the collector layer 13, the collector contact layer 12 and the substrate. The absorption layer 14 may be formed by a superlattice and particularly by an absorbing superlattice with mini bands within the conduction and valence bands. The absorption layer 14 may be formed by a superlattice of type II. In the case of a type-II superlattice, the energy gap of the two semiconductors forming the superlattice may be shifted so that carriers may be excited from the valence mini-band of one semiconductor to the conduction mini-band of the other semiconductor. The absorption layer 14 may be made of (formed by) intrinsic (or undoped) materials. Using intrinsic (or undoped) material for the superlattice enables increasing the absorption and decreasing the dark current because fewer electrons may be thermally excited. The energy gap between mini-bands in the valence and conduction band may be designed to obtain absorption of photon with appropriate energy so as to sense radiation up to a predetermined wavelength. For example, it is possible to fabricate a SWIR detector with a type II superlattice absorption layer 14 formed on the above collector layer example by 20 periods of lattice matched un-doped pairs of layers, each pair comprises of 5 nm In_{0.53}Ga_{0.47}As and 5 nm GaAs_{0.51}Sb_{0.49}. The thin InGaAs/GaAsSb layers allow formation of mini bands within the conduction and valence bands optimal for efficient optical absorption of extended wavelength SWIR radiation in a lattice matched structure with minimal defects and for optimized charge carrier transport.

The base layer 15 may be formed on the absorption layer 14. The base layer 15 may be lattice matched to the absorption layer 14, the collector layer 13, the collector contact layer 12 and the substrate. The base layer 15 may be doped so that it is of the opposite conductivity type than the emitter layer 16 and the collector layer 13. The base layer 15 may have an energy gap wider than the energy gap of the absorption layer 14. For example, it is possible to fabricate a base layer 15 formed on the above absorption layer example by 0.1 μm of p-doped GaAs_{0.51}Sb_{0.49} with a doping density of

1e17 cm⁻³.

The emitter layer 16 may be formed on the base layer 15 and be lattice matched to the base layer 15, the absorption layer 14, the collector layer 13, the collector contact layer 12 and the substrate. The emitter layer 16 may be doped of the same conductivity type than the collector layer 13. The emitter layer 16 may act as a barrier preventing reverse injection of the charge carriers from the base to flow in dark condition. The energy gap of the emitter layer 16 may be significantly superior to the energy gap of the base layer 15. In some embodiments, the emitter layer 16 may include a plurality of layers doped with the same conductivity type but with different doping densities. The emitter layer 16 may also include several layers made of different materials. In some embodiments, the phototransistor 1 may further include a spacer layer (not shown) between the base layer 15 and the emitter layer 16. The spacer layer may be doped of the same conductivity type as the emitter layer 16 and be lattice matched to it. The conduction energy level of the spacer layer may be higher than the conduction energy level of the base layer 15. The valence energy level of the spacer layer and the emitter layer 16 may be substantially equivalent. For example, it is possible to fabricate an emitter layer 16 formed on the above base layer example by growing sequentially 20 nm of n-doped In_{0.52}Al_{0.48}As spacer with a doping density of 4e16 cm⁻³, 0.1 μm of n-doped InP with a doping density of 4e16 cm⁻³, and 0.2 μm of n-doped InP with a doping density of 5e17 cm⁻³. This way recombination of holes accumulated in the base and electrons piled up between the emitter and base is avoided.

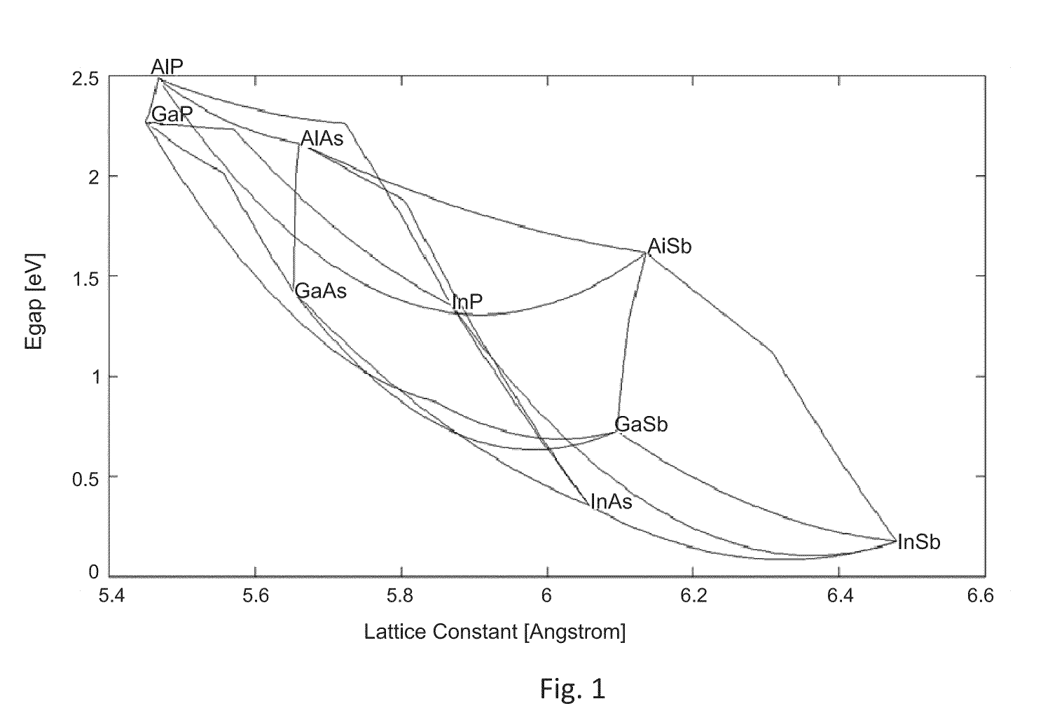

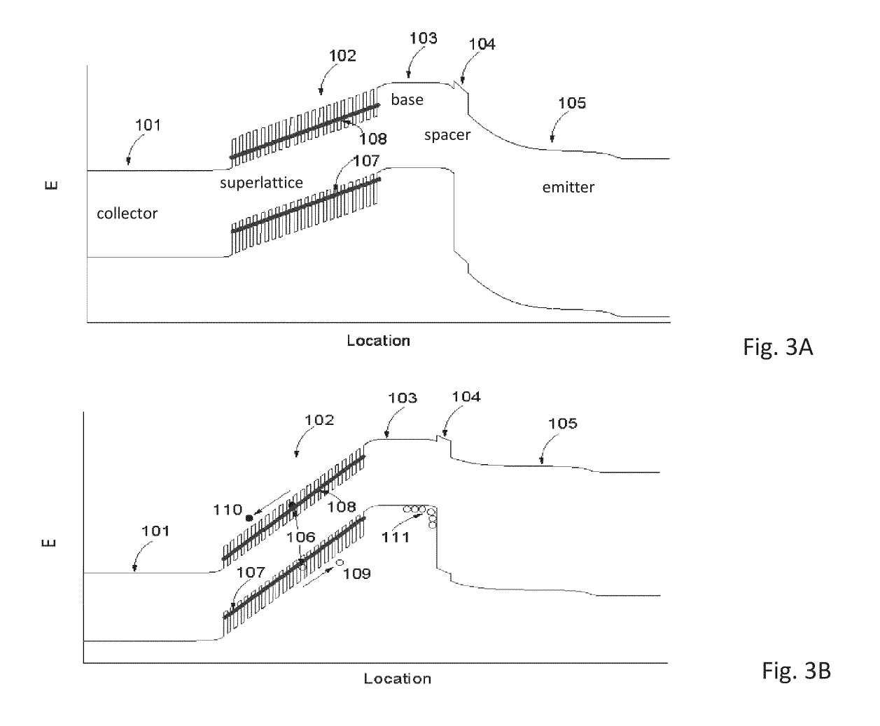

FIGS. 3A and 3B are band diagrams illustrating the energy levels of the valence and conduction bands in dark condition and in operation condition. FIG. 3B further illustrates electron-hole circulation in operation condition. The phototransistor corresponding to the exemplified band diagram comprises a collector layer, a type II superlattice absorption layer, a base layer, a spacer layer and an emitter layer. Under standard conditions of operation, a negative bias may be applied between the emitter and collector layers. The energy levels of the valence and conduction bands of the collector, absorption, base, spacer and emitter layers are respectively generally referenced 101, 102, 103, 104 and 105. The superlattice absorption layer may be generally formed of periods of two different semiconductors (for example two alloys from the alloys shown on FIG. 1). The two semiconductors forming the superlattice may be lattice matched to the substrate on which the phototransistor is manufactured. The materials (alloys) forming the different layers of the phototransistor may also be lattice matched to said substrate. The energy levels 102 of the valence and conduction bands of the absorption layer respectively comprise mini-bands 107, 108. The energy gap between the conduction mini-band 108 and the valence mini-band 107 may be designed for detection of a predetermined radiation. For example, the energy gap between the conduction mini-band 108 and the valence mini-band 107 may be designed for detection of extended wavelength SWIR up to 2.5 μm. For example, the collector may be made of n-doped InGaAs, the superlattice layer may be made of periods of intrinsic InGaAs and GaAsSb, the base layer may be made of p-doped GaAsSb, the spacer layer may be made of n-doped InAlAs and the emitter layer may be made of n-doped InP.

In general and as can be seen on FIG. 3A, in dark condition, the base forms a barrier in the conduction band against an electron flow from the emitter layer to the base layer, and the emitter forms a barrier in the valence band against a hole flow from the base to the emitter. In other words, in dark condition, due to the discontinuity between the energy bands of the spacer and emitter 104, 105 and the base 103, the device is impeded and the dark current generated by thermally exited charge carriers is very low due to low injection efficiency in the emitter base junction.

In general and as can be seen on FIG. 3B, under illumination condition, the barrier in the conduction band is lowered so as to enable photocurrent to flow from the emitter, and the barrier in the valence band stays high enough to prevent holes from flowing to the emitter. In other words, under illumination of radiation of energy superior to the energy gap of the superlattice, pairs of electron-hole, indicated by label 106, are photo-generated. The generated holes, indicated by label 109, are swept towards the base 103, and accumulated, indicated by label 111, due to the valence band discontinuity between the base 103 and the emitter 104-105. The generated electrons, indicated by label 110 are swept towards the collector 101.

In such a phototransistor device, the optical flux generates photo current that functions in a similar way to base current of three terminal bipolar transistors. The accumulated holes in the base generate photo transistor gain β which can be approximated by the ratio between the collector and base currents. According to that physical model, in our case of floating base configuration the photo transistor gain β and the optical gain of the device are identical. The gain is generated due to the accumulation of the holes in the base by increasing the injection efficiency of charge carriers between the emitter and the base which occurs in order to maintain the device charge neutrality. Since the gain β of the device increases with increasing the base current (optical current), the device has a non linear response where the optical gain increases with the optical flux. In order to avoid avalanche breakdown of the device that can increase excess noise and even damage the device in extreme, it is designed to reach punch-through breakdown earlier. Since the punch through breakdown is non-destructive and reversible the device will not be damaged and excess noise shall be minimized.

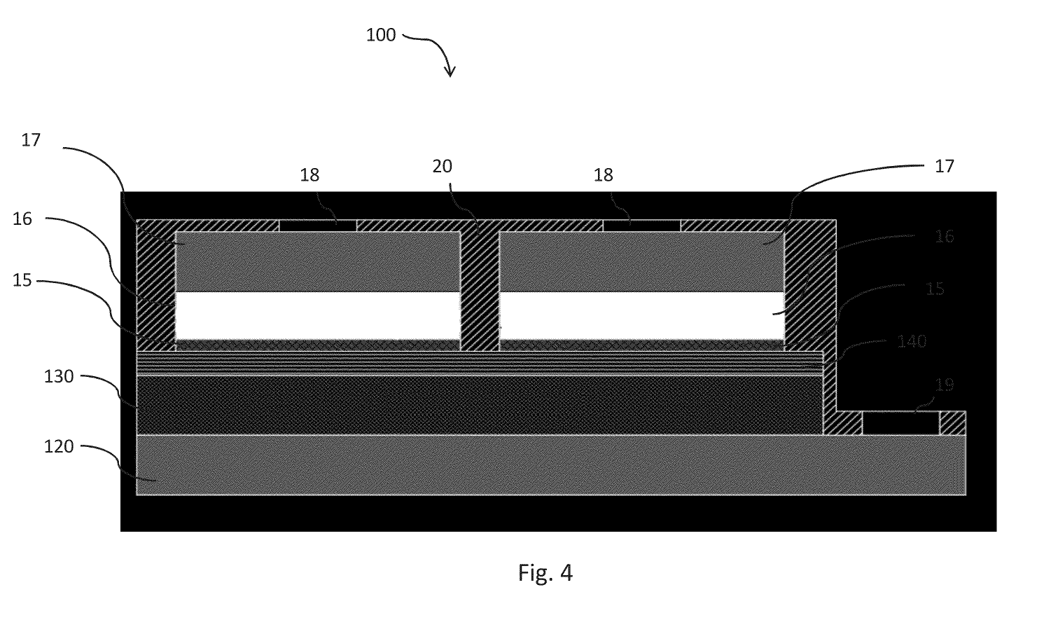

FIG. 4 illustrates a phototransistor array 100 in an embodiment of the present disclosure. The phototransistor array 100 comprises n×m phototransistors (n and m being integers). Same elements on FIG. 4 and FIG. 2 are given same numeral references. For the sake of conciseness, only the additional features with regard to the phototransistors previously described are discussed in the following. On FIG. 4, an embodiment with an array of two phototransistors is exemplified. The phototransistors comprise respectively a contact layer 120, a collector layer 130, an absorption layer 140, a base layer 15, an emitter layer 16, an emitter contact layer 17, a pixel emitter contact 18, a collector common contact 19 and a passivation layer 20. The pixel emitter contact 18 and the collector contact 19 are respectively located on the emitter contact layer 17 and collector contact layer 120 and are configured as electrical connection. As explained in the introduction, the base layer 15, the emitter layer 16 and the contact layer 17 are generally similar to these described with reference to FIG. 2. The properties of the collector contact layer 120, collector layer 130 and absorption layer 140 are also generally similar to these described with reference to FIG. 2 but the design of said layers is performed so that they are common to at least some of the phototransistors of the phototransistor matrix. In order to manufacture such phototransistor array, it is possible for example to firstly grow on the surface of a substrate a contact layer, a collector layer, an absorption layer, a base layer, an emitter layer and an emitter contact layer and to secondly etch the base layer, the emitter layer and the emitter contact layer so as to form several phototransistors sharing a common collector contact layer, collector layer and absorption layer. Further etching may be required in order to place the collector contact 19 on a peripheral area of the common contact layer 120 as shown on FIG. 4 and an emitter pixel contact 18 may be placed on at least some of the phototransistors obtained by the etching. The passivation layer 20 may be deposited over the etched side walls in order to reduce dark current generated by surface defects. Such a phototransistor array 100 may be useful for imaging purposes and the design of the phototransistor matrix and the order of the phototransistor's layers may be adapted to commercially available readout integrated circuits. As explained in the summary section, usually phototransistors are built the other way around i.e. the radiation hits the emitter having a wider bandgap therefore being transparent. Usually the base, absorbing layer and collector are made of same material with a narrower bandgap. On the other hand, the commercially available readout integrated circuits (ROIC) have a “p on n” configuration i.e. they apply negative voltage on the pixel. Therefore, the provision of a common contact layer on the collector (and not on the emitter side) enables to use standard readout circuits. Indeed, if the common contact layer was provided on the emitter the voltage polarity to be supplied by the ROIC would positive thereby preventing the use of standard ROIC.

The above examples and description have of course been provided only for the purpose of illustration, and are not intended to limit the invention in any way. As will be appreciated by the skilled person, the invention can be carried out in a great variety of ways, employing more than one technique from those described above, all without exceeding the scope of the invention.

1. A heterostructure bipolar phototransistor configured for providing an output signal in response to an external impinging light beam, said heterostructure bipolar phototransistor comprising:
an emitter region and a collector region being doped so that they are of the same conductivity type;
a base region interposed between the emitter region and the collector region, the base region being doped so that it is of the opposite conductivity type than the emitter region and the collector region; and
an absorption region interposed between the base region and the collector region, wherein the absorption region comprises a superlattice.

2. The phototransistor according to claim 1, wherein the superlattice is configured so as to provide mini-bands in the valence and conduction bands.

3. The phototransistor according to claim 2, wherein the minibands are configured to enable detection of infrared radiations with a wavelength up to 2.5 μm at room temperature.

4. The phototransistor according to claim 1, wherein the superlattice is a type II superlattice.

5. The phototransistor according to claim 1, wherein the superlattice comprises an undoped material.

6. The phototransistor according to claim 1, wherein at least one of the emitter, base, collector and absorption regions are lattice matched to each other.

7. The phototransistor according to claim 1, further comprising a spacer region between the base region and the emitter region.

8. The phototransistor according to claim 7, wherein the spacer region is part of the emitter.

9. The phototransistor according to claim 1, wherein the energy band gap of the absorption region is inferior to the energy band gap of the collector region and of the collector contact region so that the phototransistor is suitable for being back illuminated.

10. The phototransistor according to claim 1, further comprising a first contact region located above the emitter and configured for providing electric contact with the emitter region and a second contact region located below the collector and configured for providing electric contact with the collector region.

11. A phototransistor matrix comprising an array of phototransistors according to claim 9, wherein said phototransistors share a common collector region and optionally a common absorption region; the phototransistor matrix further comprising:
a first contact region configured for providing electric contact to the common collector region; and
a plurality of second contact regions configured for providing electric contact to at least some of the emitters of the phototransistors.

12. A night vision system for imaging an object, comprising:
a phototransistor matrix according to claim 11;
an optical system configured for collecting light and focusing the collected light onto the phototransistor matrix; and
a spectral filter located in an optical path of light propagating toward the phototransistor matrix, said spectral filter configured and operable to selectively filter out light of wavelength shorter than a predetermined value, thereby gradually shifting operation of the night vision system from mostly reflection mode to a combined reflection and thermal mode to allow the night vision system to detect light reflected from and emitted by the object being imaged.

13. A method of fabrication of a phototransistor comprising:
growing sequentially on a substrate a collector contact region, a collector region, an absorption region, a base region, an emitter region and an emitter contact region; wherein:
the emitter region and the collector region are doped so that they are of the same conductivity type;
the base region is doped so that it is of the opposite conductivity type than the emitter region and the collector region; and
the absorption region comprises a superlattice.

14. The method of claim 13, wherein the superlattice is formed of absorbing type II superlattice layers.

15. The method according to claim 13, wherein the superlattice is configured so that an energy band gap between mini-bands in the valence and conduction bands of the superlattice enables detection of infrared radiations with a wavelength up to 2.5 μm at room temperature.

16. The method according to claim 13, wherein the superlattice is formed of an undoped material.

17. The method according to claim 13, wherein the energy band gap of the absorption region is inferior to the energy band gap of the collector region and of the collector contact region so that the phototransistor is suitable for being back illuminated.
